(19) United States
(12) Patent Application Publication
(10) Pub. No.: US 2008/0151491 A1
(43) Pub. Date: Jun. 26, 2008

(54) SYSTEMS AND METHODS FOR COOLING RACK MOUNTED ELECTRONICS ENCLOSURES

(76) Inventors: Richard G. Baldwin, Austin, TX (US); Robert F. Poe, Liberty Hill, TX (US)

Correspondence Address: MEYERTONS, HOOD, KIVLIN, KOWERT & GOETZEL, P.C., P.O. BOX 398, AUSTIN, TX, 78767-0398, US

(21) Appl. No.: 11/961,029

(22) Filed: Dec. 20, 2007

Related U.S. Application Data
(60) Provisional application No. 60/871,360, filed on Dec. 21, 2006.

(51) Int. Cl. H05K 7/20

(52) U.S. Cl. 361/687; 361/690

(57) ABSTRACT

In various embodiments, a cool air unit may provide relatively cooler air from outside a rack to fan inlets at the rear of a rack mounted chassis (e.g., a PXI chassis). This may reduce the amount of warmer rack air in the chassis. The cooler air may be presented (e.g., made available) by the cool air unit to the inlet fans at the rear of the chassis. Because each chassis may thus have inlet air that is approximately ambient temperature (instead of an elevated temperature resulting from warmed air existing a preceding chassis in a rack), the chassis may be relatively cooler. The cool air unit may provide a system temperature reduction for system components like power supplies, controller hard drives, and other temperature sensitive modules or components.

### PRIORITY CLAIM

This application claims benefit of priority of U.S. Provisional Patent Application Ser. No. 60/871,360 titled “Systems and Methods for Optimizing Cooling Rack Mounted Electronics Enclosures”, filed on Dec. 21, 2006, whose inventors are Richard G. Baldwin Jr. and Robert F. Poe, which is hereby incorporated by reference in its entirety as though fully and completely set forth herein.

### BACKGROUND

1. Field of the Invention

The present invention relates generally to cooling systems and, more specifically, to cooling systems for electronics.

2. Description of the Related Art

Ambient temperature may be a concern within rack-mounted electronic deployments. Rack-mounted electronics chassis may also be subjected to relatively high rack temperatures due to other equipment/thermal loads within the rack. These temperatures may be quite a bit higher than the temperature outside the rack system. A simple room temperature measurement may provide an estimate of ambient temperature, but may not be the most accurate representation of the actual ambient temperature of a system (e.g., a Peripheral Component Interconnect (PCI) Extensions for Instrumentation (PXI) system). For example, heat dissipation from surrounding equipment, such as the equipment in a 19 in. rack, may artificially increase the ambient temperature. The ambient temperature of the PXI system may be defined as the temperature at the chassis fan inlet (air intake). The air intake of the chassis may be located either at the rear or other location. Due to the fact that cooling fan intakes may be located within the rack, the higher ambient temperature may affect the chassis's ability to cool the components within the chassis. If the PXI system consistently has an ambient temperature above its maximum specification, it may ultimately lead to measurement inaccuracy, system shutdown, or premature system failure. An electronics chassis subjected to higher than needed temperatures may reduce the overall system and component (hard drives, power supplies, modules etc) Mean Time Before Failure (MTBF).

### SUMMARY

In various embodiments, a cool air unit may provide relatively cooler air from outside a rack to fan inlets at the rear of a chassis (e.g., a PXI chassis). This may reduce the amount of warmer rack air in the chassis in a rack mounted chassis system. In some embodiments, the cool air unit may include a main chamber and a chassis adapter. In some embodiments, cooler air from outside the rack may enter the main chamber and be pulled through the chassis adapter to the rear of the chassis. The air may be presented (e.g., made available) by the chassis adapter to the inlet fans at the rear of the chassis. Other configurations are also contemplated. For example, the air may be pushed out of the chassis through the chassis adapter and out through the front of the main chamber. Because each chassis may have inlet air that is approximately ambient temperature (instead of an elevated temperature resulting from warmed air existing a preceding chassis in a rack), the chassis may be relatively cooler. An overall temperature reduction may be achieved with the cool air unit that may result in a similar temperature reduction for various components within the chassis and the rack. For example, the cool air unit may provide a system temperature reduction for system components like power supplies, controller hard drives and other temperature sensitive modules or components. In some embodiments, the air may be heated (e.g., by heaters in the cool air unit) before being presented to the chassis (e.g., in a low temperature environment). Other features are also described herein.

### BRIEF DESCRIPTION OF THE DRAWINGS

A better understanding of the present invention may be obtained when the following detailed description is considered in conjunction with the following drawings, in which:

FIG. 1 illustrates an isometric view of a cool air unit, according to an embodiment;

FIGS. 2a-b illustrate isometric views of the cool air unit coupled to a chassis, according to various embodiments;

FIG. 3 illustrates a rear isometric view of the cool air unit coupled to the chassis;

FIG. 4 illustrates possible chassis air intakes and outlets, according to an embodiment;

FIG. 5 illustrates a back of a chassis including two chassis fans, according to an embodiment;

FIGS. 6a-b illustrate racks of chassis/cool air units, according to various embodiments;

FIG. 7 illustrates a cool air unit with a sensor, according to an embodiment; and

FIG. 8 illustrates a flowchart of a method for using the cool air unit, according to an embodiment.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents, and alternatives falling within the spirit and scope of the present invention as defined by the appended claims. Note, the headings are for organizational purposes only and are not meant to be used to limit or interpret the description or claims. Furthermore, note that the word “may” is used throughout this application in a permissive sense (i.e., having the potential to, being able to), not a mandatory sense (i.e., must). The term “include”, and derivations thereof, mean “including, but not limited to”. The term “coupled” means “directly or indirectly connected”.

### DETAILED DESCRIPTION OF THE EMBODIMENTS

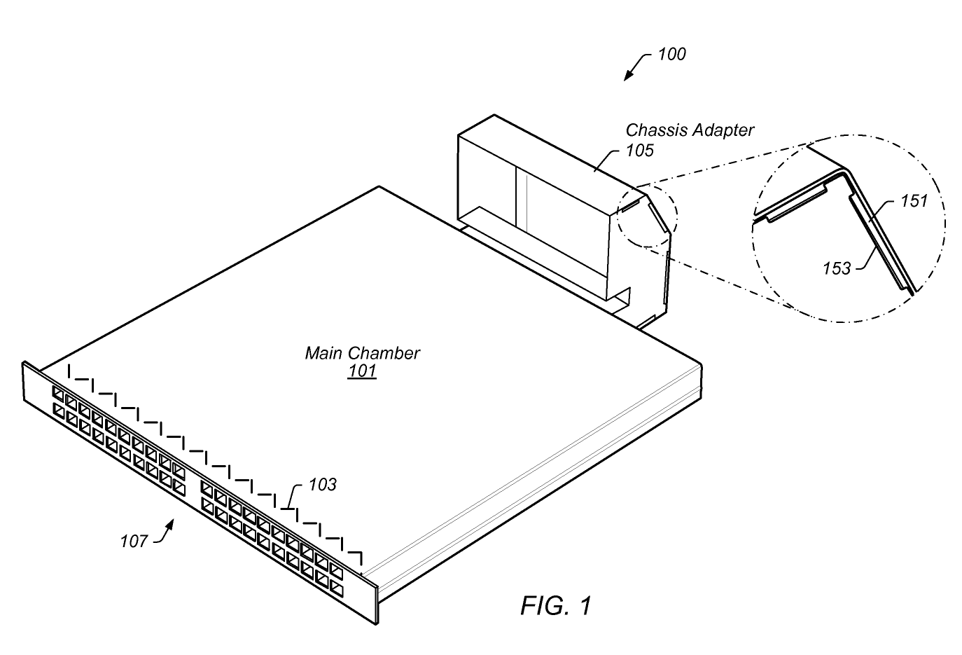

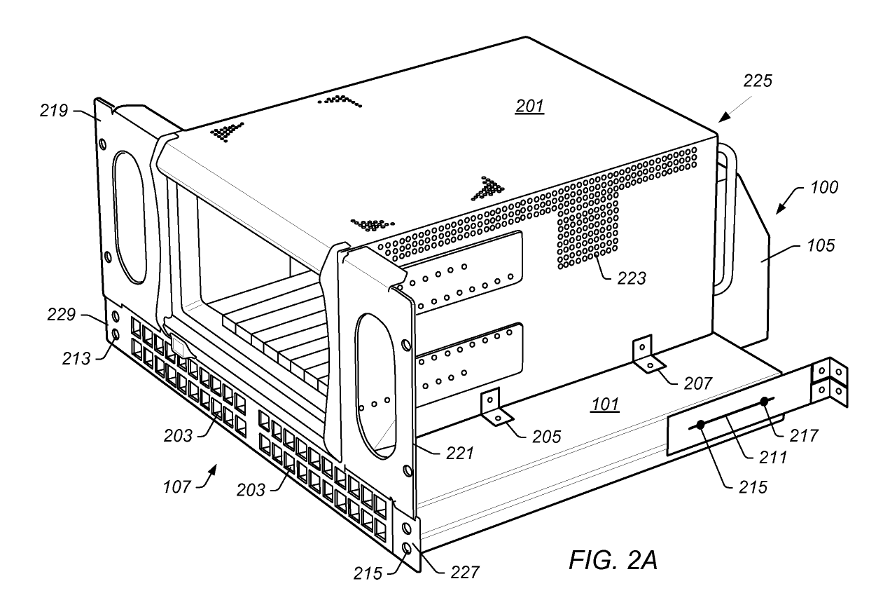

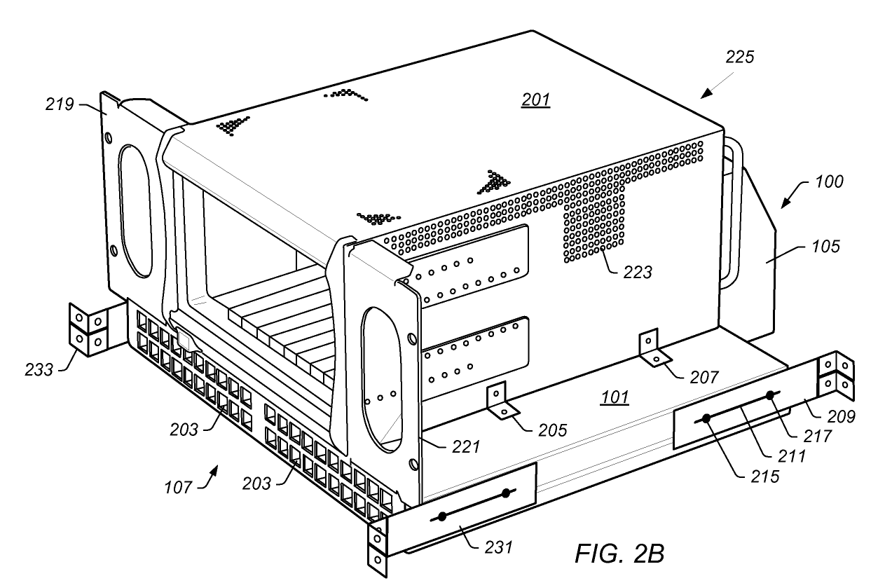

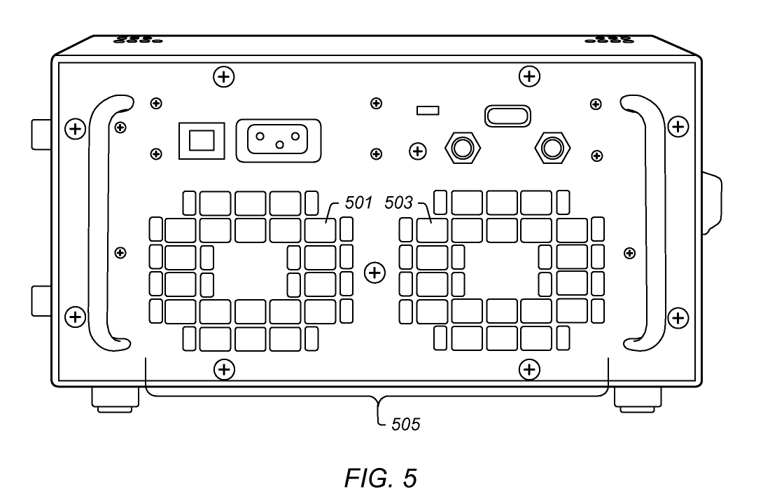

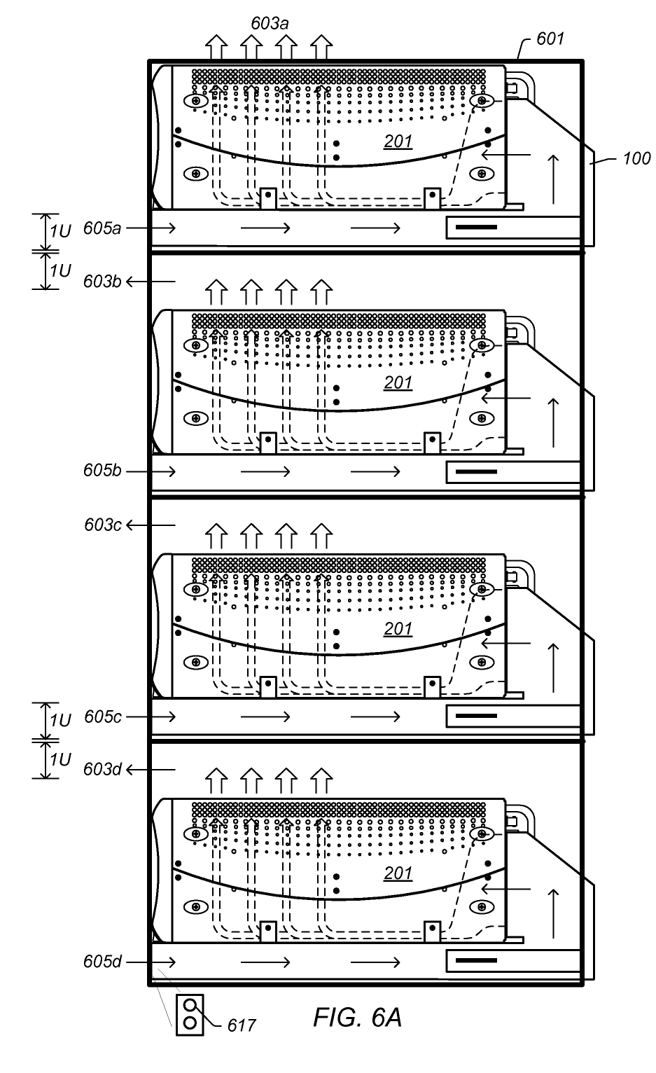

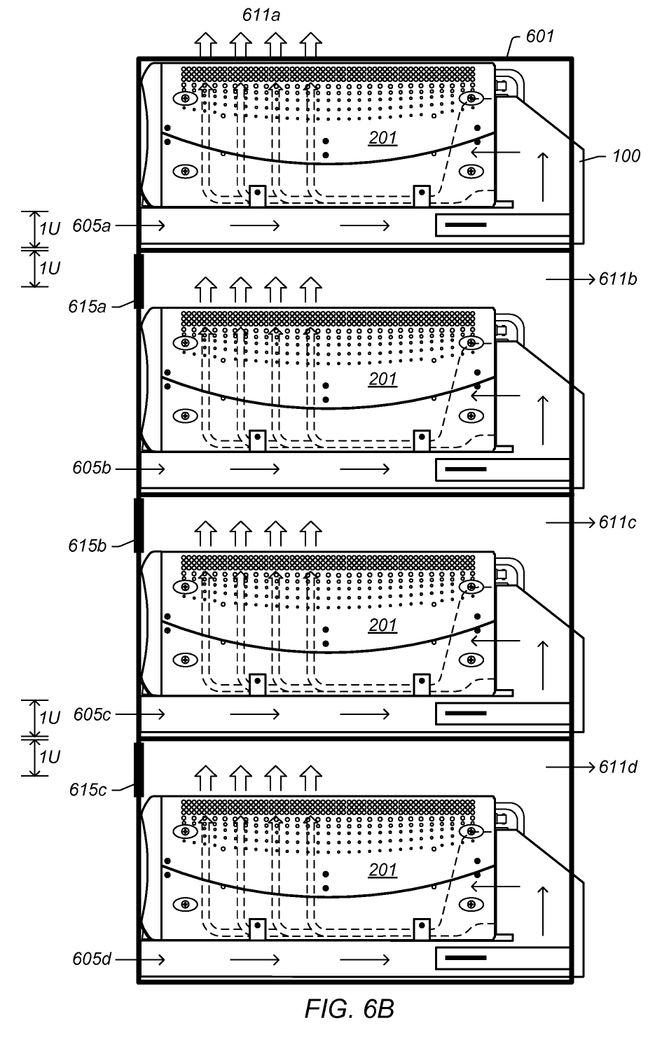

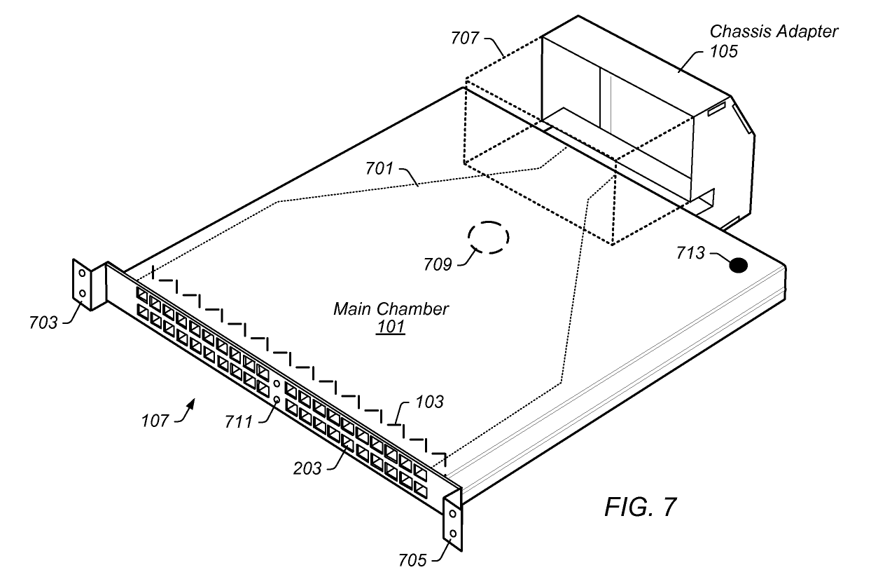

FIG. 1 illustrates an embodiment of a cool air unit 100 for a chassis 201 (e.g., a PXI chassis 201 shown in FIGS. 2a-b). Other chassis are also contemplated (e.g., compact PCI (Peripheral Component Interconnect) chassis and VXI (Versa Module Eurocard (VME) eXtensions for instrumentation chassis). In some embodiments, the cool air unit 100 may provide relatively cooler air that exists outside a rack (e.g., rack 601 shown in FIGS. 6a-b) to fan inlets at the rear of the chassis 201. This may reduce the amount of warmer rack air in the chassis (and in a rack mounted chassis system). In some embodiments, the cool air unit 100 may include two assemblies, for example, a main chamber 101 and a chassis adapter 105. In some embodiments, cooler air from outside the rack may enter the main chamber 101 and be pulled through the chassis adapter 105 to the rear of the chassis 201. The air may be presented (e.g., made available) by the chassis adapter 105 to the inlet fans 501 and 503 (see FIG. 5) at the rear of the chassis 201. Other configurations are also contemplated. For example, the chassis adapter 105 may not curve around but may instead direct the air from the main chamber 101 into a general area behind the chassis 201. In some embodiments, the air may be pushed out of the chassis 201 through the chassis adapter 105 and out through the front of the main chamber 101. Because each chassis 201 may have inlet air that is approximately ambient temperature (instead of an elevated temperature resulting from warmed air existing a preceding chassis 201), the chassis 201 may be relatively cooler. An overall temperature reduction may be achieved with the cool air unit 100 that may result in a similar temperature reduction for various components within the chassis 201 and the rack 601. For example, the cool air unit 100 may provide a system temperature reduction for system components like power supplies, controller hard drives and other temperature sensitive modules or components.

In some embodiments, the rack configuration 601 may be vented on the top and bottom (the rack 601 may have a blocked rear door and/or a closed front panel). Without the cool air unit 100, the rack configuration 601 may be subjecting the top chassis 201 to a high temperature even though the exterior rack ambient temperature may be at room temperature (e.g., 25 degrees Celsius (C)). With the cool air unit 100, the temperature of the air entering the rear 225 (from the cool air unit 100) of each stacked chassis 201 (in rack 601) may be approximately room temperature. This may result in a temperature reduction for several chassis 201 in the stacked configuration. For example, the top chassis 201 in rack 601 and its contents may be approximately 30 degrees Celsius cooler. Other temperature reductions are also contemplated.

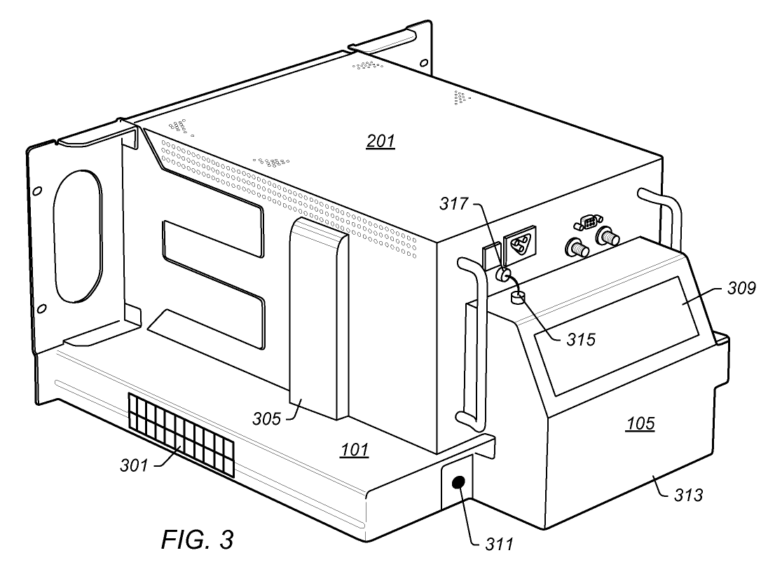

As shown, for example, in FIGS. 1 and 2a-b, the relatively cooler air may enter the front 107 (e.g., through inlet vents 203) of the cool air unit 100 (and/or, for example, through side vents 301 as seen in FIG. 3) and be routed through the main chamber 101 and chassis adapter 105 to the rear of the chassis 201 where the system fans (e.g., fans 501 and 503 as seen in FIG. 5) may reside. In some embodiments, additional fans may be placed, for example, at the front 107 of the cool air unit 100. Other locations of the fans are also contemplated.

In some embodiments, the main chamber 101 and the chassis adapter 105 may be a single piece construction (e.g., in some embodiments, the cool air unit 100 may be one assembly (e.g., welded together) without a removable chassis adapter 105). In some embodiments, the cool air unit 100 may be made of metal (e.g., sheet metal). Other materials are also contemplated. In some embodiments, the sheet metal may be formed in one or more sheets and bent to form the shapes of the main chamber 101 and/or the chassis adapter 105. In some embodiments, tabs may be formed in the sheet metal and folded over into receiving slots (e.g., see tab 151 and slot 153) of other sheet metal pieces (or the same sheet) to form the main chamber 101 and/or the chassis adapter 105. In some embodiments, the chassis adapter 105 may be coupled to the rear of the main chamber 101 (e.g., through one or more fasteners 311 such as rivets, screws, or other mounting hardware) and may be removable from the rear for air filter access. In some embodiments, a clear window 309 (e.g., a stick-on Lexan™ window) may be provided on the chassis adapter 105 for filter inspection. In some embodiments, the window 309 may be made of a clear plastic to allow the user to visually see if the filter on the rear of the chassis 201 is dirty or clogged. The user may then remove the chassis adapter 105 to service the fan filters on the rear of the chassis (in some embodiments, a different approach may be taken for bottom mounted fans). In some embodiments, the cover 313 on the cool air unit 100 may be removable. In some embodiments, the cover 313 may be fixed on the cool air unit 100.

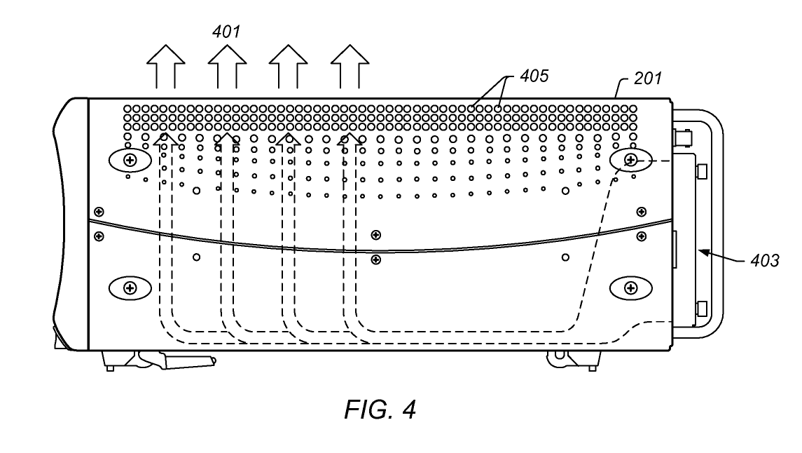

FIG. 4 illustrates an embodiment of airflow through the chassis 201. Air intake 403 may be driven, for example, by two fans 501 and 503 (e.g., as seen in FIG. 5). Air may exit the chassis 201 through the top 401 (and/or other exit points, for example, side air outlets 405).

In some embodiments, the cool air unit 100 may be mounted in rack 601 via front panel mounting brackets 227 and 229 and/or rear rack mount brackets 209. For example, mounting holes 213 and 215 in front chassis rack mount brackets 227 and 229 may be used to mount the front of the cool air unit 100 to a rack 601. In some embodiments, rear rack mount brackets 209 may be used to mount the cool air unit 100 to the rack 601. The front panel mounting brackets and rear rack mount brackets may be adjustable. For example, the rear rack mount brackets 209 may include a slide 211 with pins 215 and 217 to allow the cool air unit 100 to be adjustably mounted to the rack 601 (other numbers of pins are also contemplated). In some embodiments, the pins 215 and 217 may be tightened to fix the position of the rear rack mount brackets 209 with respect to the cool air unit 100. In some embodiments, the front and rear of the cool air unit 100 may have adjustable brackets (e.g., see front rear mounts 231 and 233 in FIG. 2b). The cool air unit 100 may also be coupled to a rack using other types and locations of chassis slides. Other adjustable mounting mechanisms are also contemplated (e.g., other bracket configurations, magnets, etc.).

Other ways of coupling the cool air unit 100 and chassis 201 are also contemplated. For example, the cool air unit 100 may be coupled to the rack 601 via only the front chassis rack mount brackets (e.g., which may be fixed or may slide). The rear of the chassis 201 may be supported via the cool air unit 100 itself. In some embodiments, the chassis 201 may be located above the cool air unit 100 and may be attached to the rack 601 separately. In some embodiments, the cool air unit 100 may act as a shelf for the chassis 201 to rest on if the user does not want to use rack mount brackets on the chassis 201 itself. This may allow the chassis 201 to be removable independently of the cool air unit 100. In some embodiments, the cool air unit 100 may be mounted to the rack 601 on slides allowing the cool air unit to be easily removed/installed into the rack 601.

In some embodiments, guides 205 and 207 may be used to receive the module 201. For example, the guides 205 and 207 may be used to receive the chassis 201 after the cool air unit 100 has been mounted to the rack 601. In some embodiments, corresponding guides and rear rack mounts may also be provided on the other side of the cool air unit 100. The guides 205/207 may be attached to the chassis 201 (e.g., after the chassis 201 is placed on the cool air unit 100). In some embodiments, the guides 205/207 may be only coupled to the cool air unit 100 (e.g., and not attached to the chassis 201). In some embodiments, chassis rack mount brackets 219 and 221 may be further used to center the chassis 201 and mount the chassis 201 to the rack 601. In some embodiments, the chassis rack mount brackets 219 and 221 may be adjustable (e.g., adjustable forward and backward) on the chassis 201 (e.g., the mount the chassis 201 recessed into a rack). The chassis rack mount brackets 219 and 221 may be adjustable on the chassis 201 through fasteners along the side of the chassis 201. In some embodiments, the chassis 201 may be installed or removed from the rack 601 with the cool air unit 100 already in place. Alignment features may help guide the chassis 201 into the proper position so that the chassis adapter 105 may mate correctly to the rear of the chassis 201. In some embodiments, chassis rack mount brackets (e.g., mounting spacers 219 and 221) may be configured to allow the chassis 201 to be recessed into the chassis 201 (e.g., a user may use an appropriate chassis adapter 105 or the adapter 105 may be adjustable for the fore/aft dimension to accommodate a recessed chassis 201).

Dust intrusion between the cool air unit 100 inlet and the system fans may need to be minimized (e.g., the air flow characteristics of the cool air unit 100 may include a vacuum that pulls in additional dust). In some embodiments, a foam seal may be provided between the chassis inlet vent/finger guard 505 and the chassis adapter 105 to minimize dust intrusion. In some embodiments, the chassis adapter 105 may mate against the rear of the chassis 201 and may provide a seal (e.g., a reasonably tight seal) to prevent dust and air (e.g., hot air) from entering the adapter 105 and then the chassis 201.

In some embodiments, if the front of the cool air unit 100 is filtered, the chassis adapter 105 may not need to be removed by a user for dust removal (in some embodiments, it may be removed by the user even with front air filters). In addition, servicing the chassis air filters may be improved if the filter 103 is re-located to the front of the cool air unit 100 (e.g., at the front of the chamber 101/rack 601). This may result in the user not having to access the rear of the chassis 201 to clean the air filters. In some embodiments, the air filter 103 might be corrugated to improve filter surface area (e.g., if the filter surface area is otherwise reduced because of a smaller area in the front of the main chamber 101). In some embodiments, the cool air unit 100 may not have an air filter relocated to the front of the cool air unit 100 (e.g., front mounted air filters may have size limitations or air flow limitations). In some embodiments, the front of the cool air unit 100 and/or the front mounted air filters may be configured to avoid size and air flow limitations.

In some embodiments, a possible main chamber 101/chassis adapter 105 configuration may include a main chamber 101 that has a common shape for 8 to 18 slot chassis 201. Custom adapters 105 may be provided for the different chassis 201 (e.g., 1042/1042Q, 1062Q and 1045 chassis 201). In some embodiments, dimensional differences between chassis may be accounted for by using different shapes for the main chamber 101. In some embodiments, the main chamber 101 and chassis adapter 105 may be unique for each chassis 201 architecture. In some embodiments, the intake area at the front of main chamber 101 may be reduced for the 8-slot chassis 201 (and may be more reduced for the 18-slot chassis 201). This may have an affect on the system airflow but may not negate the cooling performance increase due to the intake air temperature reduction.

Other configurations for the cool air unit are also contemplated. In some embodiments, power supply intake 223 may pull air from inside the power supply shuttle and the vents on the right side of the chassis 201. The cool air unit 100 may be configured to deliver air to these intakes (e.g., through extended ducts 305 that are connected to the main chamber 101 such that air flowing through the main chamber 101 may flow through the extended duct 305). Other extended ducts are also possible (e.g., to other air intakes on the chassis 201). In some embodiments, cool air unit 100 may route cool air to other fan inlet locations, like bottom-mounted fans for example. In some embodiments, the cool air unit 100 may have other ducts/adapters on it to cool other portions of the chassis 201 (e.g., air intakes on the side of the chassis 201 for power supply cooling, etc.). In some embodiments, the cool air unit 100 may have an internal funnel shaped structure 701. In some embodiments, front mount brackets may be extended from the cool air unit 100 (e.g., front mount brackets 703 and 705). In some embodiments, the length of the front mount brackets 703 and 705 may be configured to allow different insets of the chassis 201 (e.g., to accommodate larger chassis and/or to allow more inset of smaller chassis). In some embodiments, the chassis adapter may have a longer engaging duct 707 (e.g., for engaging smaller and/or set-in chassis 201).

As seen in FIGS. 6a-b, the cool air unit 100 may route cool air from the front of an electronics rack 601 (e.g., air flow 605a-d) to the rear of the chassis 201 (e.g., with a rear fan intake) and thus may reduce the chassis 201 intake air temperature. In some embodiments, the cool air unit 100 may be used with a chassis 201 surrounded by other equipment (e.g., equipment that does not include a chassis). Use of the cool air unit 100 may result in cooler electronics and improved component life. In some embodiments, exiting air flow (e.g., air flows 603a-d) may deliver warm air out of the rack 601. In some embodiments, the exiting air flows (e.g. air flows 611b-611d) may also deliver warmer air into the rear of the rack. In some embodiments, filler panels 615a-c may be added to the rack to block warm air from flowing out of the front of the rack 601 (and mixing with incoming air flows 605a-d). This may result in air flows 605a-d being cooler than if these air flows mixed with the exiting air (which may be directed out of the rear of the rack 611b-d and the top of the rack 611a). Other air flows are also contemplated. In some embodiments, the rear of the rack may not have a rear door (to allow air out). In some embodiments, the rear of the rack may be enclosed and may allow air to exit through ventilation air holes. Other rack configurations are also contemplated. In some embodiments, the rear of the rack may extend past the edge of the chassis adapter 105. While a separate cool air unit 100 is shown with each chassis in rack 601, other embodiments may use fewer cool air units 100 than chassis. For example, the rack 601 may use only one cool air unit 100 located in the middle of the rack 601. Other configurations are also contemplated.

In some embodiments, the rack may be an EIA STD rack (e.g., an Electronic Industries Alliance standard rack). In some embodiments, the front portion of the cool air unit 100 may be approximately 1 U high (e.g., approximately 1.75 inches high). In some embodiments, the cool air unit 100 may use approximately 1 U of vertical rack space between the chassis 201. In some embodiments, the air outlet for the front of the rack (e.g., for air flows 603a-c) may be approximately 1 U high. Other heights for the cool air unit 100 and portions of the cool air unit 100 such as the front portion and the air outlet are also contemplated (e.g., 0.5 U or 2 U). In some embodiments, greater heights may lead to greater cooling of the racked components. In some embodiments, the main chamber 101 may be shared (e.g., leveraged) between different widths and sizes of chassis 201. The main chamber 101 may be different for each chassis 201 width/size. In some embodiments, the cool air unit 100 may be designed to work with chassis 201 mounted in other ways (e.g., standing vertically within a rack 601).

In some embodiments, the cool air unit 100 may include an electrical connection to the chassis 201 that may allow it to communicate with the chassis 201 (e.g., chassis connector 317 connected to cool air unit connector 315). Other communication links are also contemplated. The communication link may allow the chassis 201 to send/receive signals from the cool air unit 100 (e.g., the chassis 201 may send a request to activate and/or increase the speed of additional cooling fans within the cool air unit 100 (e.g., which may be located in the front of the main chamber 100 or in the chassis adapter 105)). Other locations for additional fans are also contemplated. The electrical connection may also be used to allow the chassis 201 to send a request to the cool air unit 100 to operate a heater in the cool air unit 100 (e.g., in the main chamber 101 or chassis adapter 105) to allow for operation in a lower ambient temperature environment (e.g., a heater may be located in the front of the cool air unit 100 to allow operation of the chassis 201 in a below freezing ambient environment). The electrical connection may be used to allow the chassis 201 to communicate with other sensors 709 housed in or on the cool air unit 100 (e.g., sensors to measure temperature, humidity, air flow, pressure, etc.). The sensors may be located in/on the main chamber 101 and/or the chassis adapter 105. In some embodiments, the cool air unit 100 may have built in circuitry that may assist in communication with the chassis 201 (e.g., through the electrical connection). In some embodiments, the cool air unit 100 may be able to present data to the user (e.g., via Light Emitting Diodes (LEDs) 711 on the front panel of the cool air unit 100). In some embodiments, the cool air unit 100 may have a connector (e.g., connector 713) located on it to allow other communication with the chassis 201. In some embodiments, the cool air unit 100 may relocate signals (e.g., clock in/out, remote inhibit or fan control setting) to the front of the cool air unit 100 for access by the user or may transmit the signals out of the cool air unit (e.g., through connector 713) to an external unit.

The cool air unit 100 may provide significant temperature reductions for chassis 201 (e.g., within PXI rack mount applications). These temperature reductions may in turn increase the life of critical system components such as power supplies, fans, hard drives and other critical components.

In some embodiments, users may use the cool air unit 100 and proper installation and maintenance to improve system-cooling performance (e.g., in rack mounted applications such as the rack 601 shown in FIGS. 6a-b). If the system (e.g., a PXI system) is deployed in a rack 601, there may be several additional guidelines that may be considered. For example, high power units may be placed within the rack 601 above the PXI system(s) where possible. In some embodiments, racks 601 may be used with open sides and/or rear panels. Fan trays may also be used within the rack 601, including at the top and bottom of the rack 601, to increase overall air flow to reduce ambient temperatures within the rack 601.

When assembling the rack 601, components (e.g., instruments, chassis 201, etc.) that radiate more heat may be placed in locations that may reduce the increase in the ambient temperature of the PXI system. In some embodiments, airflow may be increased through fan trays and other cool-air-intake devices. Rack-mount fan trays may bring relatively cool outside air inside a rack. A fan tray may be installed near the PXI system to further reduce the ambient temperature.

In some embodiments, adequate cooling clearances may be used to ensure that the ambient temperature of the PXI system is within the specifications for the system components. The air intakes on the chassis 201 may be located at the rear or bottom of the chassis 201. In some embodiments, air outlet apertures may be located in the top and along both sides of the chassis 201, or in the top, bottom, front, rear, and along the right side of the chassis 201. These apertures may facilitate, for example, power supply and module cooling.

In some embodiments, the chassis 201 may be installed so the cooling clearances air intake and the air outlets may have adequate ventilation. An example clearance for a PXI chassis 201 with a rear air intake and top/side exhaust may include providing a minimum of 76.2 mm (3 in.) of clearance from the air intake on the rear of the chassis 201 and 44.5 mm (1.75 in.) of clearance above and on the sides of the chassis 201. An 18-slot chassis 201 may use 1.75 in. of clearance above the chassis 201. In some embodiments, a minimum of 44.5 mm (1.75 in.) of clearance from the air outlets on the chassis 201 may be provided for adequate venting (e.g., 1 U if the chassis 201 is rack mounted). Other clearances are also contemplated. For example, high-power applications may require additional cooling clearances.

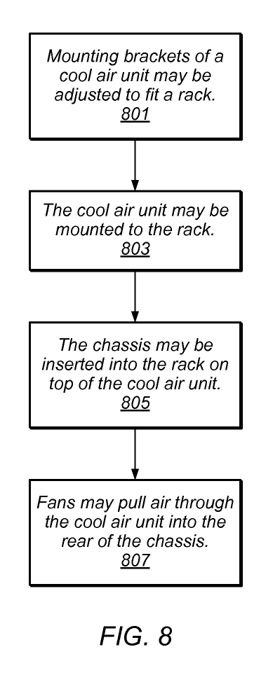

FIG. 8 illustrates a flowchart of a method for using the cool air unit 100, according to an embodiment. It should be noted that in various embodiments of the methods described below, one or more of the elements described may be performed concurrently, in a different order than shown, or may be omitted entirely. Other additional elements may also be performed as desired.

At 801, one or more mounting brackets (e.g., rear rack mount brackets 209 and/or front panel mounting brackets 227 and 229, etc.) of a cool air unit 100 may be adjusted to fit a rack 601. For example, pins 215 and 217 may slide along slide 211 and may be secured (e.g., pins 215 and 217 may include fasteners such as screws or bolts that can be tightened to hold a position in the slide 211).

At 803, the cool air unit 100 may be mounted to the rack 601 (e.g., screws, bolts, etc. may be used through holes 213, 215 of brackets 229,227 and through corresponding holes 617 of rack 601. The cool air unit 100 may be secured to the rack 601 through the front and/or rear of the rack 601.

At 805, the chassis 201 may be inserted into the rack 601 on top of the cool air unit 100. In some embodiments, the cool air unit 100 may be coupled to the cool air unit 100 through fasteners (such as screws, bolts, etc.) through the holes of guides 205 and/or 207 and through corresponding holes of the chassis 201. In some embodiments, the chassis 201 may be coupled to the cool air unit 100 prior to either being inserted into the rack 601. In some embodiments, the chassis 201 may be coupled to the rack 601 in addition to or in place of coupling the chassis 201 to the cool air unit 100.

At 807, fans (e.g., fans 501, 503) may pull air through the cool air unit 100 into the rear of the chassis 201. Air may enter through inlet vents 203, be pulled through the main chamber 101, through the chassis adapter 105 and into the chassis 201. In some embodiments, the fans may be located in the cool air unit 100. In some embodiments, air may be pushed out of the chassis 201, through the chassis adapter 105, through the main chamber 101, and out the vents in the front 107. Other air flows are also contemplated.

Embodiments of a subset or all (and portions or all) of the above may be implemented by program instructions stored in a memory medium or carrier medium and executed by a processor. For example, communications between the chassis 201 and sensors 709, cool air unit circuitry, etc. and instructions to fans, heaters, etc. may be stored and/or directed through program instructions. A memory medium may include any of various types of memory devices or storage devices. The term “memory medium” is intended to include an installation medium, e.g., a Compact Disc Read Only Memory (CD-ROM), floppy disks, or tape device; a computer system memory or random access memory such as Dynamic Random Access Memory (DRAM), Double Data Rate Random Access Memory (DDR RAM), Static Random Access Memory (SRAM), Extended Data Out Random Access Memory (EDO RAM), Rambus Random Access Memory (RAM), etc.; or a non-volatile memory such as a magnetic media, e.g., a hard drive, or optical storage. The memory medium may comprise other types of memory as well, or combinations thereof. In addition, the memory medium may be located in a first computer in which the programs are executed, or may be located in a second different computer that connects to the first computer over a network, such as the Internet. In the latter instance, the second computer may provide program instructions to the first computer for execution. The term “memory medium” may include two or more memory mediums that may reside in different locations, e.g., in different computers that are connected over a network.

In some embodiments, a computer system at a respective participant location may include a memory medium(s) on which one or more computer programs or software components according to one embodiment of the present invention may be stored. For example, the memory medium may store one or more programs that are executable to perform the methods described herein. The memory medium may also store operating system software, as well as other software for operation of the computer system.

Further modifications and alternative embodiments of various aspects of the invention may be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. An apparatus, comprising:
a main chamber;
a vent coupled to the main chamber;
a chassis adapter coupled to the main chamber;
wherein the main chamber is configured to receive air through the vent and wherein the chassis adapter is configured to receive the air from the main chamber; and
wherein the chassis adapter is configured to present the air to a rear of a chassis.

2. The apparatus of claim 1, wherein the chassis is a Peripheral Component Interconnect (PCI) Extensions for Instrumentation (PXI) chassis.

3. The apparatus of claim 1, wherein the main chamber is coupled to a rack through at least one front panel mounting bracket.

4. The apparatus of claim 1, wherein the main chamber is coupled to a rack through at least one adjustable rear rack mount bracket.

5. The apparatus of claim 1, wherein the main chamber is configured to receive a chassis placed on top of the main chamber.

6. The apparatus of claim 1, wherein the main chamber further comprises at least one side vent.

7. The apparatus of claim 1, wherein the main chamber further comprises at least one extended duct to present air to an air inlet on a side of the chassis.

8. The apparatus of claim 1, wherein the chassis adapter further comprises a window for viewing inside the chassis adapter.

9. The apparatus of claim 1, further comprising a connector configured to connect to a chassis for receiving signals from the chassis.

10. The apparatus of claim 1, further comprising at least one filter mounted in a front portion of the main chamber.

11. The apparatus of claim 1, wherein the chassis adapter is coupled to the main chamber through a screw.

12. The apparatus of claim 1, wherein the main chamber further comprises at least one sensor.

13. A rack-mounted system, comprising:
a rack;
a cool air unit mounted to the rack, comprising:
a main chamber;
a vent coupled to the main chamber;
a chassis adapter coupled to the main chamber;
wherein the main chamber is configured to receive air through the vent and wherein the chassis adapter is configured to receive the air from the main chamber;
wherein the chassis adapter is configured to present the air to a rear of a chassis; and
wherein the chassis is placed relative to the cool air unit such that the chassis receives air from the chassis adapter.

14. The rack-mounted system of claim 13, wherein the cool air unit is one of a plurality of cool air units mounted to the rack; and wherein at least two of the plurality of cool air units each present air to a separate corresponding chassis.

15. The rack-mounted system of claim 13, wherein the chassis is a Peripheral Component Interconnect (PCI) Extensions for Instrumentation (PXI) chassis.

16. The rack-mounted system of claim 13, wherein the main chamber is coupled to a rack through at least one front panel mounting bracket and at least one adjustable rear rack mount bracket.

17. The rack-mounted system of claim 13, wherein the main chamber further comprises at least one side vent.

18. The rack-mounted system of claim 13, wherein the main chamber further comprises at least one extended duct to present air to an air inlet on a side of the chassis.

19. The rack-mounted system of claim 13, further comprising a connector configured to connect to a chassis for receiving signals from the chassis.

20. The rack-mounted system of claim 13, further comprising at least one filter mounted in a front portion of the main chamber.

21. An apparatus, comprising:
a main chamber;
a vent coupled to the main chamber;
a chassis adapter coupled to the main chamber;
wherein the chassis adapter is configured to receive air from a rear of a chassis;
wherein the main chamber is configured to receive the air from the chassis adapter; and
wherein the vent is configured to deliver the air out of the main chamber.

22. The apparatus of claim 21, wherein the chassis is a Peripheral Component Interconnect (PCI) Extensions for Instrumentation (PXI) chassis.
